(19) United States
(12) Patent Application Publication
(10) Pub. No.: US 2010/0096730 A1
(43) Pub. Date: Apr. 22, 2010

(54) PASSIVATION TECHNIQUE

(75) Inventor: Simon Jonathan Stacey, Cambridgeshire (GB)

Correspondence Address: GREENBERG TRAURIG, LLP, 77 WEST WACKER DRIVE, SUITE 3100, CHICAGO, IL, 60601-1732, US

(73) Assignee: CAMBRIDGE SILICON RADIO LTD., Cambridge (GB)

(21) Appl. No.: 12/568,233

(22) Filed: Sep. 28, 2009

(30) Foreign Application Priority Data
Oct. 16, 2008 (GB) 0818963.1

(51) Int. Cl. H01L 21/304; H01L 23/58

(52) U.S. Cl. 257/620; 438/462; 257/E21.237; 257/E23.002

(57) ABSTRACT

A method of semiconductor wafer fabrication. The wafer is fabricated by receiving a semiconductor wafer having a substrate layer and at least one processed layer, cutting a trench into the wafer, wherein the trench penetrates through the at least one processed layer and only partially through the thickness of the substrate layer, and depositing a passivation layer over the at least one processed layer such that the trench is filled with the passivation material.

### TECHNICAL FIELD

The present invention relates to passivation during semiconductor wafer manufacture and in particular to edge passivation during wafer level processing of chip scale packages.

### BACKGROUND

Advances in techniques for packaging semiconductor die are being driven by the market for smaller, lower cost electronic devices with increasing functionality. Chip scale packaging (CSP) encompasses a number of different packaging techniques where the size of the packaged die is only slightly larger than the size of the die itself (e.g. a ratio of areas which does not exceed 1.2:1). In one example of CSP, the die may be mounted onto a package on which solder balls (or bumps) are formed (e.g. a ball grid array package), such that the die is electrically connected to the package by means of wirebonds and the assembled package may be mounted onto a printed circuit board (PCB) using BGA techniques or flip-chip bonding.

In wafer level chip scale packaging (WLCSP), also referred to as wafer level packaging, the solder balls (or bumps) are formed directly on the semiconductor wafer, before the wafer is diced into individual die. This results in a very compact packaged die and enables wafer scale testing of packaged die, which may have cost and efficiency benefits.

The wafer is diced into die which are then mounted in an appropriate manner. The dicing step leaves the edges of the die exposed, leading to the possibility of moisture ingress or other damage to the die. It has been proposed to encapsulate completed dies to protect the die from its surrounding environment, but such processes are complex and expensive to implement as they require additional processes and specialist materials beyond those conventionally utilised in wafer processing.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a first aspect there is provided a method of semiconductor wafer fabrication, comprising the steps of receiving a semiconductor wafer comprising a substrate layer and at least one processed layer; cutting a trench into the wafer, wherein the trench penetrates through the at least one processed layer and only partially through the thickness of the substrate layer; and depositing a passivation layer over the at least one processed layer such that the trench is filled with the passivation material.

In a second aspect there is provided a semiconductor wafer, comprising a substrate layer and at least one processed layer; at least one trench cut into the wafer, wherein the trench penetrates through the at least one processed layer and only partially through the thickness of the wafer substrate; and a passivation layer, wherein the passivation layer fills the at least one trench to coat the ends of layers exposed in the trench.

In a third aspect there is provided a die, comprising a substrate layer and at least one processed layer, and a passivation layer coating exposed edges of the at least one processed layer.

The trench may be cut along scribe lanes between dies.

The trench may surround at least one die and follow the line along which that die will be singulated from the wafer.

The method may further comprise the step of singulating the wafer into individual dies along the trench, wherein the width of the singulation cut is less than the width of the trench. The trench may penetrate the substrate layer by less than 5% of the substrate layer thickness.

The wafer may be a Silicon wafer.

The trench may be cut using a trench saw or by laser ablation.

The wafer may be singulated using a saw or laser ablation.

The width of the trench may be in the range 55-60 μm.

The trench may penetrate the substrate by a greater distance than the thickness of the substrate after a backgrind has been performed.

The method may further comprise the step of backgrinding the wafer.

The backgrind may not penetrate into the trench.

The backgrind may penetrate into the trench.

The trench may lie along scribe lanes between dies.

The trench may surround at least one die and follow the line along which that die will be singulated from the wafer.

The width of the trench may be wider than the kerf width of the cutter which will be used to singulate the wafer.

The trench may penetrate the substrate layer by less than 5% of the substrate layer thickness.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a cross-section of a wafer after initial processing;

FIG. 2 is a flow chart of a method of semiconductor wafer manufacture;

FIG. 3 shows a cross section of a wafer after cutting of the trench;

FIG. 4 shows a cross section of a wafer after the first passivation layer has been applied;

FIG. 5 shows a cross section of a wafer after completion of wafer level processing;

FIG. 6 shows a cross section of a wafer after backgrind;

FIG. 7 shows a cross section of a wafer during singulation; and

FIG. 8 shows a cross section of a wafer having a deep trench.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

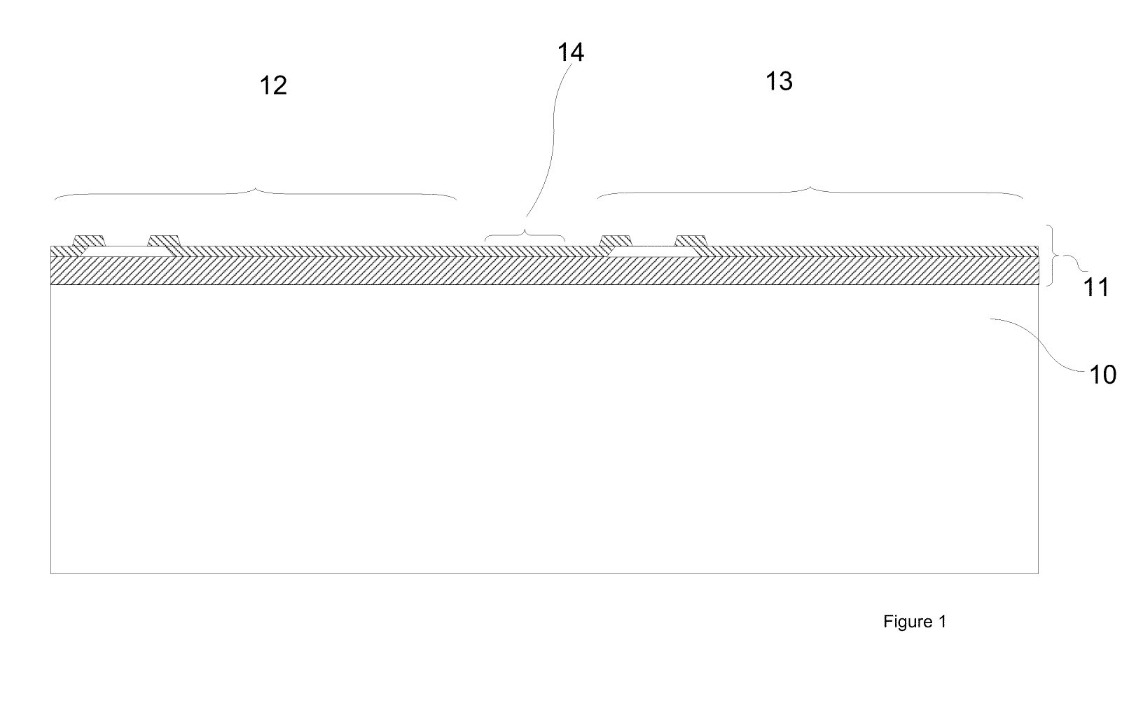

FIG. 1 shows a cross-section of part of a wafer following silicon processing and prior to wafer level processing steps. The wafer comprises a substrate region 10 and processed layers 11. The cross-section of FIG. 1 encompasses two dies 12, 13, separated by a scribe lane 14 which divides the dies such that they can be diced without damaging the active regions of the die. For the purposes of this description a Silicon substrate is referred to, but as will be appreciated the methods and techniques described herein may be applicable to a wide range of material systems. In conventional Wafer Level Chip Scale Package processing, further processing is conducted at the wafer level and subsequently the wafer is diced into individual dies for mounting. As explained previously, the dicing step leaves the edge of processed layers of the die exposed and thus susceptible to moisture ingress.

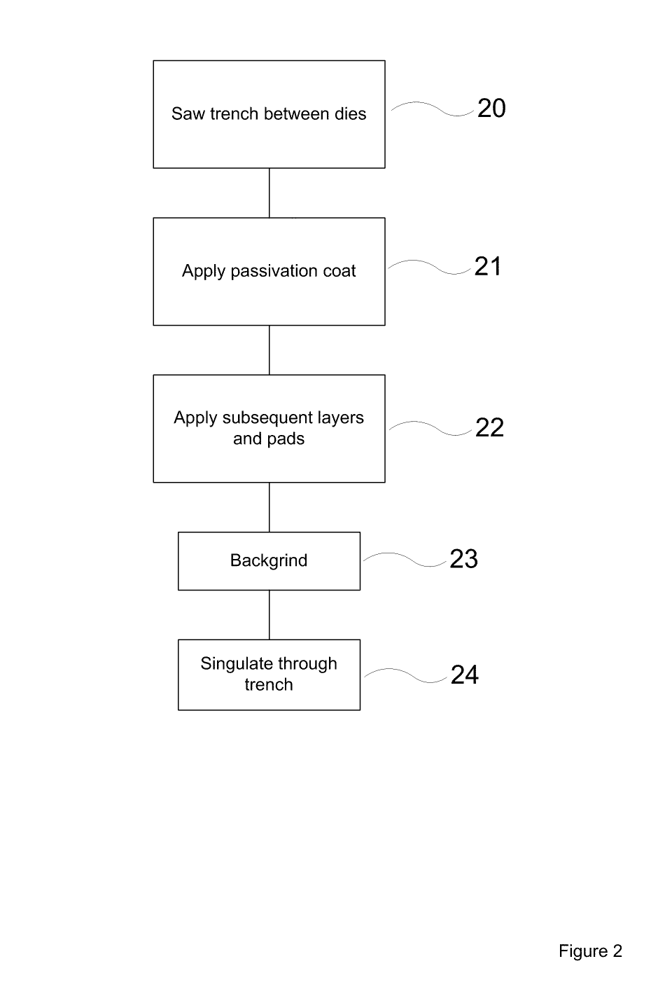

FIG. 2 shows a flow chart of a method of wafer-level processing according to an embodiment of the current invention.

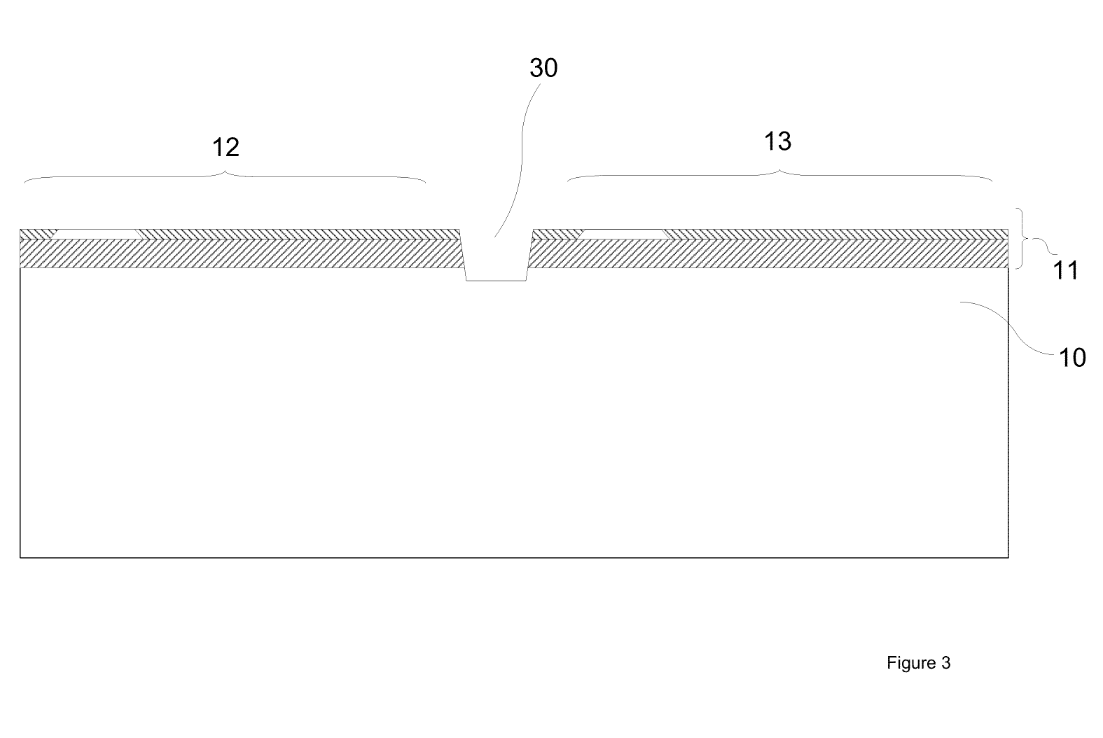

At block 20 a trench 30 is cut between the dies along the scribe lane. The trench 30 is sufficiently deep to penetrate through the processed layers 11 and into the substrate Silicon 10, thereby exposing the edge of each of the processed layers of the die. The kerf width of the saw is selected to be wider than the kerf width of the singulation saw that will be used to dice the wafer into individual die. FIG. 3 shows a cross-section of the wafer after the trench 30 has been cut.

A typical wafer has a thickness of 725-775 μm, which is reduced to 125-430 μm during the backgrind process. For example, a 200 mm wafer may start with a thickness of 725 μm and be background to 370 μm to provide a 0.6 mm max height WLCSP product when populated with 250 μm solder balls prior to reflow. The trench 30 may be cut to extend 5-10 μm into the substrate Silicon 10. The trench depth is therefore small in comparison to the overall thickness of the substrate and would not have a significant effect on the mechanical properties of the substrate during wafer level processing. The depth of the trench is selected dependent upon the material system and process parameters and therefore may be significantly greater or smaller than the values suggested in this example. For example, the trench may penetrate less than 2% in to the substrate silicon.

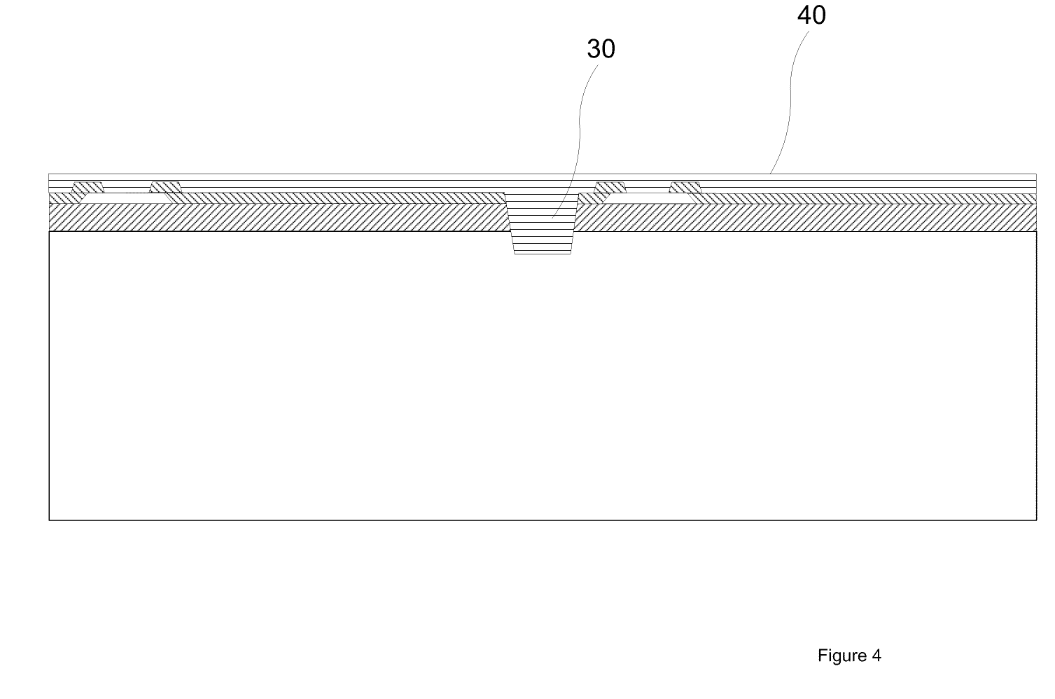

At block 21 the first passivation layer 40 is deposited on the wafer. The passivation layer 40 is deposited such that the trench 30 is filled by the passivation material. For example, a conventional photo definable polyimide passivation film could be spin coated to fill and planarise the trenches. FIG. 4 shows a cross-section of the wafer after the passivation layer 40 has been applied. Filling of the trench is ensured by the selection of suitable process parameters, which is within the skill of the person skilled in the art.

In conventional processes it is common to pattern the passivation layer such that there is no passivation layer in the scribe lane due to the presence of Process Control Monitoring (PCM) structures affecting the adhesion of the passivation layer and, hence, the subsequent die singulation yield. The resultant topologies generated by removing the passivation layer(s) in the scribe lane can cause metal “stringers” which require additional etch steps to remove. In the current method the PCM structures are removed by the trench cutting step and thus the passivation layer need not be patterned in the scribe lanes. The overall process is therefore simplified. Although patterning of the passivation layer over the scribe lane is not required in the current method, it may be performed if required due to other processing considerations.

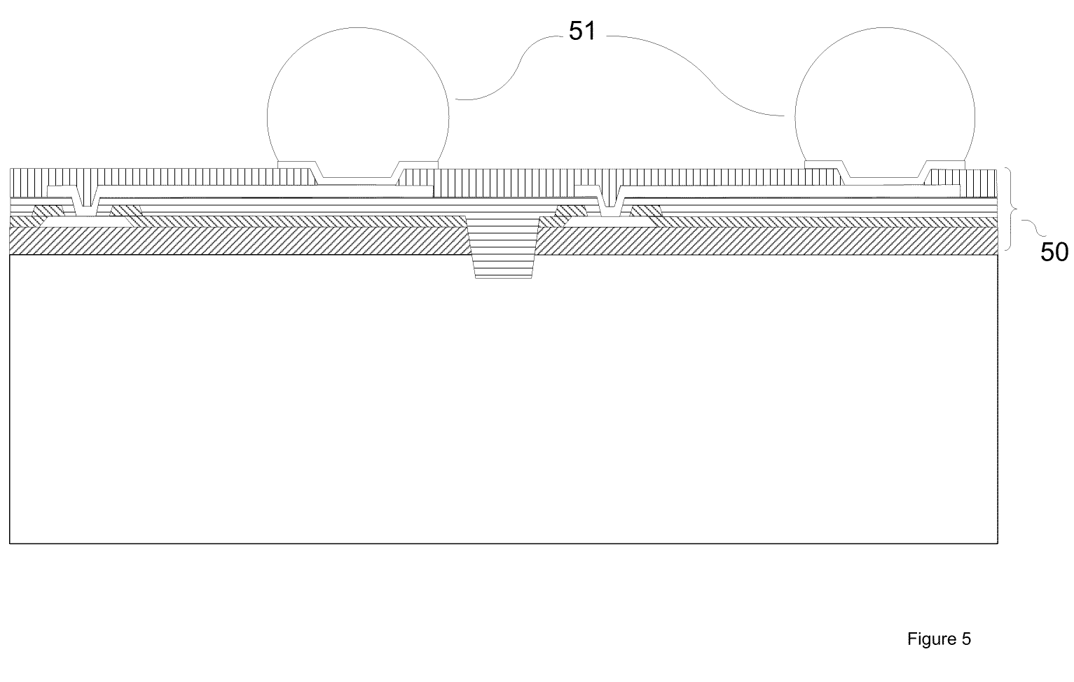

At block 22 processing of the wafer continues according to the usual process steps of the production technique being utilised. FIG. 5 shows a cross-section after completion of the Wafer Level processing steps for an exemplary fabrication process. Each die includes a number of metal and insulator layers 50, and solder balls or bumps 51 for connection to a package.

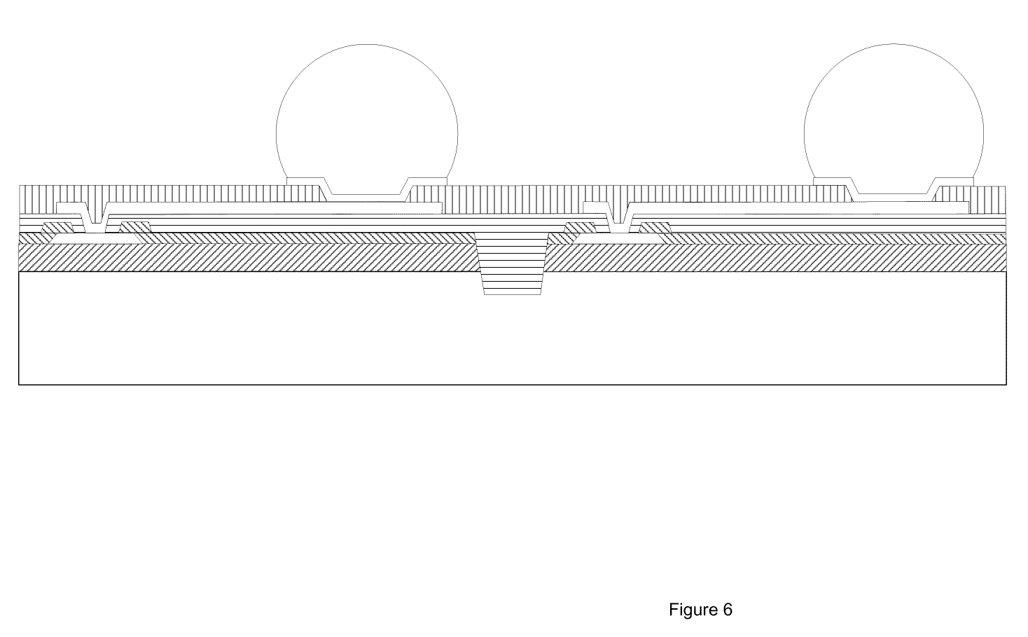

At block 23 a backgrind is performed to reduce the substrate to the required thickness, as shown in FIG. 6.

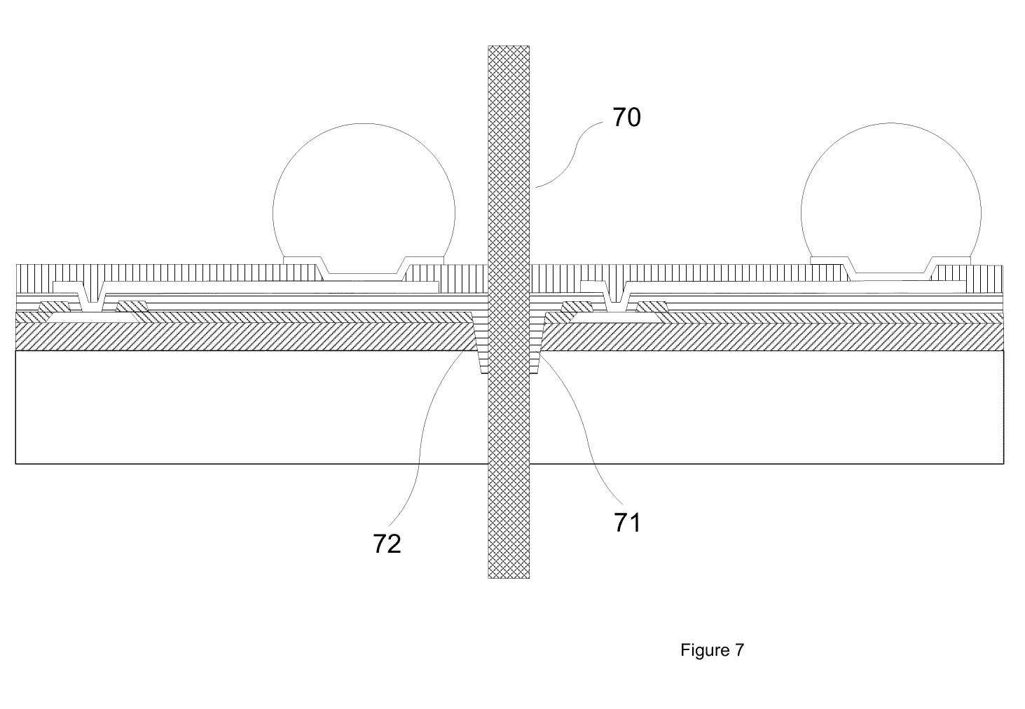

At block 24 the wafer is singulated along the scribe lanes, through the trench. FIG. 7 shows a cross-section of the wafer including the singulation saw 70. Since the width of the trench is wider than the kerf width of the singulation saw 70, passivation material 71 remains on the sides of the trench. The edges 72 of the processed Silicon layers of the die are therefore covered with a passivation layer, which protects against moisture ingress.

The method described in relation to FIG. 2 thereby provides a die in which the edges of the processed layers have a passivation coating. The method utilises known techniques, materials which are already part of the process and does not require significant modification of the overall fabrication process.

The thickness of the passivation layer on the edges of the die is defined by the difference between the kerf width of the trench saw and the kerf width of the singulation saw. A typical effective passivation layer thickness is 5-10 μm and a typical singulation saw kerf width is 35-50 μm (a two stage singulation cut may be utilised, using, for example, 45 μm and then 35 μm kerf widths). A 55-65 μm trench would therefore provide a suitable passivation thickness after singulation. Any suitable combination of kerf widths may be utilised to achieve a required passivation thickness within the confines of the scribe lane width, which may be 80 μm. The kerf width of the trench saw may also be selected such that all of the PCM structures are removed during the trench cutting step.

Certain processes (for example 0.13 μm lithographic processes) utilise Aluminium pads and Copper metallization layers. In conventional processing, the dice step may leave Copper layers of the PCM structures exposed at the edge of the die. Those layers may form a galvanic cell with the device Aluminium contact pads leading to corrosion of the die pads. In the current process, the PCM structures are either removed by the trench cut, or are passivated, thereby preventing the formation of a galvanic cell.

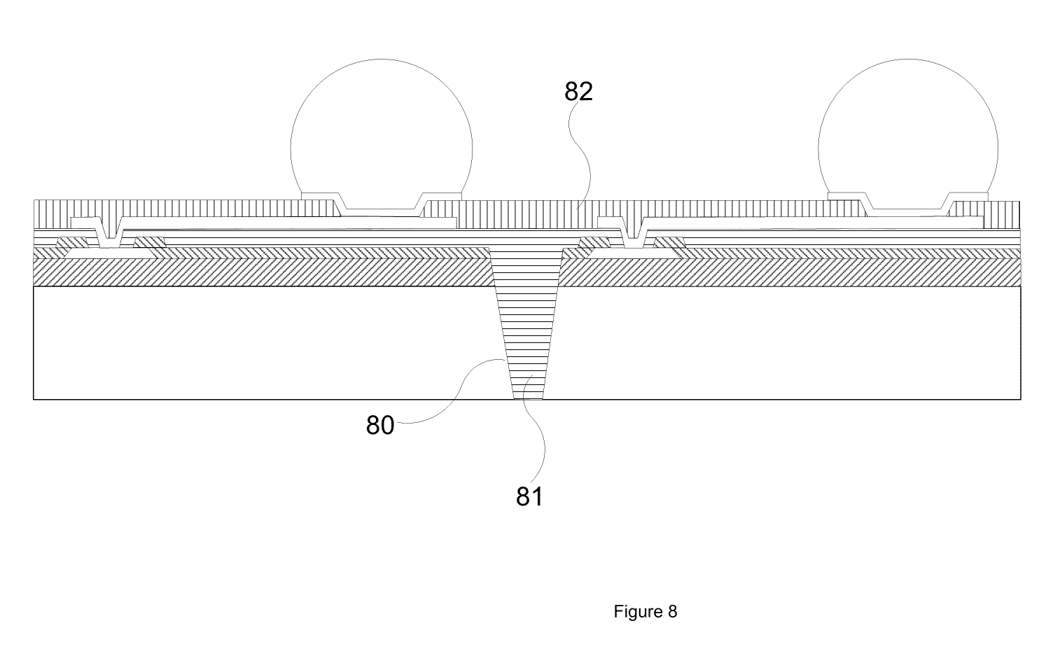

The trench may also be cut to a significantly greater depth than shown above such that the backgrind step penetrates into the bottom of the trench. FIG. 8 shows a cross section of a wafer with a deeper trench 80 after backgrind. The singulation step on such a wafer is performed only through the passivation layers 81, 82 (and any unpatterned layers), which may reduce the cutting time and may improve the suitability of alternative cutting techniques such as laser ablation due to the simplification of the layer structure. Also, the whole edge of the die is coated, whereas a shallow trench leaves part of the substrate edge uncoated. This would give the added benefit of reducing the level of backside chipping during the singulation step.

As will be appreciated by the skilled person, references to cutting or dicing are intended to refer to all methods of performing those steps and include the use of saws, laser ablation techniques and any other appropriate technique. Saws are referred to for example only and this is not restrictive of techniques included.

Although the above description has been made with reference to scribe lanes between dies on a wafer, the general techniques forming the method may be utilised in other areas of a wafer.

The embodiments described herein are not limited to implementations which solve any or all of the disadvantages of known wafer level chip scale packages and packaging techniques. Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought. The methods have been described with reference to only a selection of steps which may form part of an overall fabrication method. Additional processing steps may be performed without departing from the scope of the methods described herein.

Furthermore, constituent steps may be performed using different equipment, at different locations or by different parties.

It will be understood that the above description of a preferred embodiment is given by way of example only and that various modifications may be made by those skilled in the art.

Although various embodiments have been described above with a certain degree of particularity, or with reference to one or more individual embodiments, those skilled in the art could make numerous alterations to the disclosed embodiments without departing from the spirit or scope of this invention.

What is claimed is:

1. A method of semiconductor wafer fabrication, comprising the steps of
receiving a semiconductor wafer comprising a substrate layer and at least one processed layer;
cutting a trench into the wafer, wherein the trench penetrates through the at least one processed layer and only partially through the thickness of the substrate layer; and
depositing a passivation layer over the at least one processed layer such that the trench is filled with the passivation material.

2. The method according to claim 1, wherein the trench is cut along scribe lanes between dies.

3. The method according to claim 2, wherein the trench surrounds at least one die and follows the line along which that die will be singulated from the wafer.

4. The method according to claim 1, further comprising the step of singulating the wafer into individual dies along the trench, wherein the width of the singulation cut is less than the width of the trench.

5. The method according to claim 1, wherein the trench penetrates the substrate layer by less than 5% of the substrate layer thickness.

6. The method according to claim 1, wherein the wafer is a Silicon wafer.

7. The method according to claim 1, wherein the trench is cut using a trench saw.

8. The method according to claim 1, wherein the trench is cut using laser ablation.

9. The method according to claim 4, wherein the wafer is singulated using a saw.

10. The method according to claim 4, wherein the wafer is singulated using laser ablation.

11. The method according to claim 1, wherein the width of the trench is in the range 55-60 μm.

12. The method according to claim 1, wherein the trench penetrates the substrate by a greater distance than the thickness of the substrate after a backgrind has been performed.

13. The method according to claim 1, further comprising the step of backgrinding the wafer.

14. The method according to claim 13, wherein the backgrind does not penetrate into the trench.

15. The method according to claim 13, wherein the backgrind penetrates into the trench.

16. A semiconductor wafer, comprising
a substrate layer and at least one processed layer;
at least one trench cut into the wafer, wherein the trench penetrates through the at least one processed layer and only partially through the thickness of the wafer substrate; and
a passivation layer, wherein the passivation layer fills the at least one trench to coat the ends of layers exposed in the trench.

17. The wafer according to claim 16, wherein the trench lies along scribe lanes between dies.

18. The wafer according to claim 17, wherein the trench surrounds at least one die and follows the line along which that die will be singulated from the wafer.

19. The wafer according to claim 16, wherein the width of the trench is wider than the kerf width of the cutter which will be used to singulate the wafer.

20. The wafer according to claim 16, wherein the trench penetrates the substrate layer by less than 5% of the substrate layer thickness.

21. The wafer according to claim 16, wherein the wafer is a Silicon wafer.

22. The wafer according to claim 16, wherein the width of the trench is in the range 55-60 μm.

23. The wafer according to claim 16, wherein the trench penetrates the substrate by a greater distance than the thickness of the substrate after a backgrind has been performed.

24. A die, comprising
a substrate layer and at least one processed layer, and
a passivation layer coating exposed edges of the at least one processed layer.
